(19) United States
(12) Patent Application Publication
(10) Pub. No.: US 2019/0220219 A1
(43) Pub. Date: Jul. 18, 2019

(54) MEMORY DEVICE AND METHOD OF OPERATING THE SAME

(71) Applicant: SK hynix Inc., Gyeonggi-do (KR)

(72) Inventor: Gi Pyo UM, Gyeonggi-do (KR)

(21) Appl. No.: 16/109,301

(22) Filed: Aug. 22, 2018

(30) Foreign Application Priority Data
Jan. 18, 2018 (KR) 10-2018-0006667

(51) Int. Cl. G06F 3/06; G11C 16/14

(52) U.S. Cl. CPC G06F 3/0652; G11C 16/14; G06F 3/0613; G11C 16/10; G06F 3/0658; G06F 3/0679; G06F 3/0659

(57) ABSTRACT

A memory device includes a memory cell array including a plurality of memory cells, a peripheral circuit configured to perform a background erase operation on memory cells selected from among the plurality of memory cells, and a control logic configured to control, when a foreground operation command is inputted while the background erase operation is being performed, the peripheral circuit so that the background erase operation is suspended in response to input of a confirm command for the foreground operation command.

### CROSS-REFERENCE TO RELATED APPLICATION

The present application claims priority under 35 U.S.C. § 119(a) to Korean patent application number 10-2018-0006667, filed on Jan. 18, 2018, the entire disclosure of which is incorporated herein by reference in its entirety.

### BACKGROUND

### Field of Invention

Various embodiments of the present disclosure generally relate to an electronic device and, more particularly, to a memory device and a method of operating the memory device.

### Description of Related Art

Memory devices are storage devices embodied using a semiconductor such as silicon (Si), germanium (Ge), gallium arsenide (GaAs), indium phosphide (InP), or the like. Memory devices are chiefly classified into a volatile memory device and a nonvolatile memory device.

Representative examples of the nonvolatile memory include a read only memory (ROM), a programmable ROM (PROM), an electrically programmable ROM (EPROM), an electrically erasable programmable ROM (EEPROM), a flash memory, a phase-change random access memory (PRAM), a magnetic RAM (MRAM), a resistive RAM (RRAM), and a ferroelectric RAM (FRAM).

### SUMMARY

Various embodiments of the present disclosure are directed to a memory device for performing a background erase operation and a method of operating the memory device.

An embodiment of the present disclosure may provide for a memory device. The memory device may include a memory cell array including a plurality of memory cells, a peripheral circuit configured to perform a background erase operation on memory cells selected from among the plurality of memory cells, and a control logic configured to control, when a foreground operation command is inputted while the background erase operation is being performed, the peripheral circuit so that the background erase operation is suspended in response to input of a confirm command for the foreground operation command.

An embodiment of the present disclosure may provide for a method of operating a memory device including a plurality of memory cells. The method may include receiving a background erase command for memory cells selected from among the plurality of memory cells from an external controller, performing a background erase operation on the selected memory cells, receiving a foreground operation command for any memory cells, among the plurality of memory cells while the background erase operation is being performed, and suspending the background erase operation in response to input of a confirm command for the foreground operation command.

An embodiment of the present disclosure may provide for a memory device. The memory device may include a plurality of memory cells, a peripheral circuit configured to perform an operation to the memory cells and a control logic configured to control the peripheral circuit to perform a background erase operation while a foreground operation is not performed, wherein the control logic configured to control the peripheral circuit to keep performing the background erase operation until all information required for performing the foreground operation is provided.

### BRIEF DESCRIPTION OF THE DRAWINGS

FIG. 1 is a diagram illustrating a storage device.

FIG. 2 is a diagram illustrating the pin structure of a memory device shown in FIG. 1.

FIG. 3 is a block diagram illustrating the structure of the memory device shown in FIG. 1.

FIG. 4 is a diagram for explaining an input/output operation and a cell operation of a memory device during a program operation.

FIG. 5 is a diagram for explaining a background erase operation in accordance with an embodiment of the present disclosure.

FIG. 6 is a diagram illustrating the structure of a background erase operation processing unit shown in FIG. 3.

FIG. 7 is a flowchart illustrating the operation of a memory device in accordance with an embodiment of the present disclosure.

FIG. 8 is a flowchart illustrating the operation of the memory device in accordance with an embodiment of the present disclosure.

FIG. 9 is a diagram illustrating an embodiment of a memory cell array shown in FIG. 3.

FIG. 10 is a circuit diagram illustrating any one memory block BLKa of memory blocks BLK1 to BLKz shown in FIG. 9.

FIG. 11 is a circuit diagram illustrating an example of any one memory block BLKb of the memory blocks BLK1 to BLKz shown FIG. 9.

FIG. 12 is a circuit diagram illustrating an embodiment of a memory cell array shown in FIG. 3.

FIG. 13 is a block diagram illustrating a memory system including the memory device shown in FIG. 3.

FIG. 14 is a block diagram illustrating an example of application of the memory system shown in FIG. 13.

FIG. 15 is a block diagram illustrating a computing system including the memory system described with reference to FIG. 14.

### DETAILED DESCRIPTION

Specific structural or functional descriptions in the embodiments of the present disclosure introduced in this specification or application are only for description of the embodiments of the present disclosure. The descriptions should not be construed as being limited to the embodiments described in the specification or application.

The present disclosure will not be described in detail based on embodiments. The present disclosure may, however, be embodied in many different forms and should not be construed as being limited to only the embodiments set forth herein, but should be construed as covering modifications, equivalents or alternatives falling within ideas and technical scopes of the present invention. However, this is not intended to limit the present disclosure to particular modes of practice, and it is to be appreciated that all changes, equivalents, and substitutes that do not depart from the spirit and technical scope of the present disclosure are encompassed in the present disclosure.

It will be understood that, although the terms “first” and/or “second” may be used herein to describe various elements, these elements should not be limited by these terms. These terms are only used to distinguish one element, from another element. For instance, a first element discussed below could be termed a second element without departing from the teachings of the present disclosure. Similarly, the second element could also be termed the first element.

It will be understood that when an element is referred to as being “coupled” or “connected” to another element, it can be directly coupled or connected to the other element or intervening elements may be present therebetween. In contrast, it should be understood that when an element is referred to as being “directly coupled” or “directly connected” to another element, there are no intervening elements present. Other expressions that explain the relationship between elements, such as “between”, “directly between”, “adjacent to” or directly adjacent to” should be construed in the same way.

The terminology used herein is for the purpose of describing particular embodiments only and is not intended to be limiting. In the present disclosure, the singular forms are intended to include the plural forms as well, unless the context clearly indicates otherwise. It will be further understood that the terms “comprise”, “include”, “have”, etc. when used in this specification, specify the presence of stated features, integers, steps, operations, elements, components, and/or combinations of them but do not preclude the presence or addition of one or more other features, integers, steps, operations, elements, components, and/or combinations thereof.

Unless otherwise defined, all terms including technical and scientific terms used herein have the same meaning as commonly understood by one of ordinary skill in the art to which the present disclosure belongs. It will be further understood that terms used herein should be interpreted as having a meaning that is consistent with their meaning in the context of this specification and the relevant art and will not be interpreted in an idealized or overly formal sense unless expressly so defined herein.

Detailed description of functions and structures well known to those skilled in the art will be omitted to avoid obscuring the subject matter of the present disclosure. This aims to omit unnecessary description so as to make the subject matter of the present disclosure clear.

Various embodiments of the present disclosure will now be described more fully hereinafter with reference to the accompanying drawings, in which preferred embodiments of the present disclosure are shown, so that those of ordinary skill in the art can easily carry out the technical idea of the present disclosure.

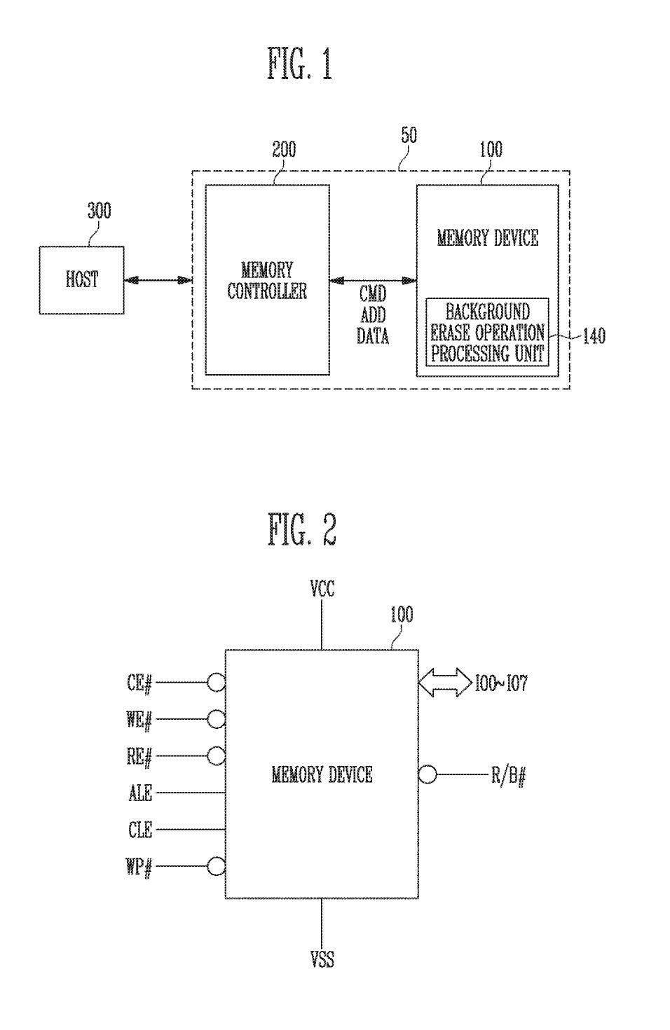

FIG. 1 is a diagram illustrating a storage device.

Referring to FIG. 1, a storage device 50 may include a memory device 100 and a memory controller 200.

The memory device 100 may store data. The memory device 100 is operated in response to the control of the memory controller 200. The memory device 100 may include a plurality of memory cells which store data. Each of a plurality of memory cells included in each memory block may be implemented as any one of a single-level cell (SLC) capable of storing a single data bit, a multi-level cell (MLC) capable of storing two data bits, a triple-level cell (TLC) capable of storing three data bits, and a quad-level cell (QLC) capable of storing four data bits.

In an embodiment, examples of the memory device 100 may include a double data rate synchronous dynamic random access memory (DDR SDRAM), a low power DDR SDRAM fourth generation (LPDDR4 SDRAM), a graphics double data rate (GDDR) SDRAM, a low power DDR (LPDDR) SDRAM, a Rambus DRAM (RDRAM), a NAND flash memory, a vertical NAND flash memory, a NOR flash memory device, a resistive RAM (RRAM), a phase-change memory (PRAM), a magnetoresistive RAM (MRAM), a ferroelectric RAM (FRAM), or a spin transfer torque RAM (STT-RAM).

The memory device 100 may receive a command CMD and an address ADD from the memory controller 200, and may access a region selected by the address ADD. That is, the memory device 100 may perform an operation corresponding to the command CMD on the region selected by the address ADD. For example, the memory device 100 may perform a program operation, a read operation, and an erase operation. During a program operation, the memory device 100 may program data to the region selected by the address ADD. During a read operation, the memory device 100 may read data from the region selected by the address ADD. During an erase operation, the memory device 100 may erase data stored in the region selected by the address ADD.

In an embodiment, the program operation and the read operation may be performed on a page basis, and the erase operation may be performed on a block basis.

The memory controller 200 may control the overall operation of the memory device 100. The memory controller 200 may control the operation of the memory device 100 in response to a request received from a host 300 or regardless of the request received from the host 300.

For example, the memory controller 200 may control the memory device 100 so that a program operation, a read operation or an erase operation is performed in response to the request received from the host 300. During a program operation, the memory controller 200 may provide a program command, an address, and data to the memory device 100. During a read operation, the memory controller 200 may provide a read command and an address to the memory device 100. During an erase operation, the memory controller 200 may provide an erase command and an address to the memory device 100.

In an embodiment, the memory controller 200 may autonomously generate a program command, an address, and data without receiving a request from the host, and transmit them to the memory device 100. For example, the memory controller 200 may provide commands, addresses, and data to the memory device 100 to perform background operations, such as a program operation for wear leveling and a program operation for garbage collection.

The memory controller 200 may run firmware (FW) for controlling the memory device 100. When the memory device 100 is a flash memory device, the memory controller 200 may operate firmware such as a Flash Translation Layer (FTL) for controlling communication between the host 300 and the memory device 100. More specifically, the memory controller 200 may translate a logical address included in a request received from the host 300 into a physical address which is an address ADD to be provided to the memory device 100.

In accordance with an embodiment of the present disclosure, the memory device 100 may perform a background operation. For example, the memory device 100 may receive a background erase command and an address ADD from the memory controller 200. The memory device 100 may perform a background erase operation on a memory block corresponding to the address ADD.

The memory device 100 may include a background erase operation processing unit 140. The background erase operation processing unit 140 may perform a background erase operation. The background erase operation may be performed while the memory device 100 is in an idle state. In the idle state, the memory device 100 performs no foreground operation. In an embodiment, the background erase operation may be performed before the input of a confirm command indicating that the transmission of a foreground operation command and related address and data is completed.

In an embodiment, the foreground operation command may indicate of any one of a program operation, a read operation, and an erase operation as a foreground operation. For example, the foreground operation command may be any one of a program command, a read command, and an erase command.

In detail, the background erase operation processing unit 140 may identify whether the command CMD inputted from the memory controller 200 is a background erase command. When the background erase command is inputted, the background erase operation processing unit 140 may perform an erase operation on a memory block in response to the background erase command while the memory device 100 is in an idle state. While the background erase command is executed, the memory device 100 may receive a command CMD, an address ADD, and data DATA for the foreground erase operation.

When a foreground operation command is inputted while the background erase operation is being performed, the background erase operation processing unit 140 may perform the background erase operation until a confirm command corresponding to the foreground operation command is inputted. When the confirm command is inputted, the background erase operation processing unit 140 may suspend the background erase operation, and may store background erase status information. The background erase status information may indicate the degree to which the background erase operation progresses. For example, the background erase status information may indicate at least one of the number of applications of an erase voltage pulse, the number of performed erase loops, the voltage level of the applied erase voltage pulse, and the erase verification result.

The background erase operation processing unit 140 may suspend the performance of the background erase operation until a foreground operation is completed in response to a foreground operation command. When the foreground operation is completed in response to the foreground operation command, the background erase operation processing unit 140 may then resume the suspended background erase operation based on the stored background erase status information. For example, the background erase operation processing unit 140 may resume the background erase operation from the suspended position of the memory block on which the background erase operation was performed at the time of the suspension, without performing the erase operation from the start position of the memory block, depending on the stored background erase status information, i.e., based on at least one of the number of applications of the erase voltage pulse, the number of performed erase loops, the voltage level of the applied erase voltage pulse, and the erase verification result.

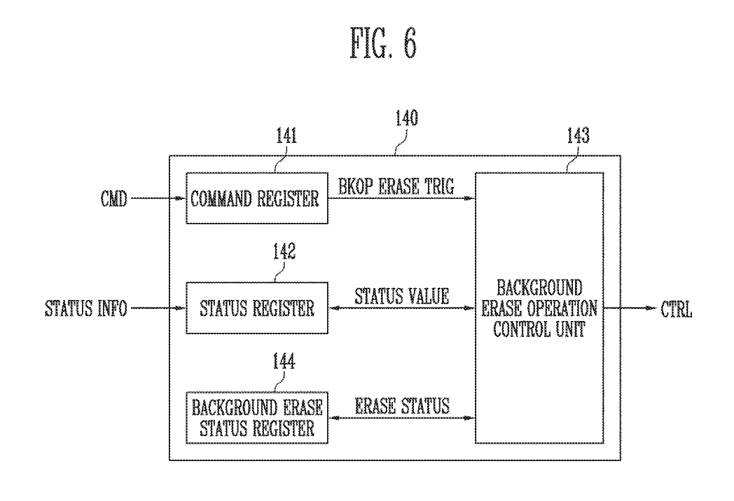

In various embodiments, the background erase operation processing unit 140 may determine whether a foreground operation command, which is inputted while the background erase operation is being performed, indicates an erase operation on a memory block on which the background erase operation is being performed. When the inputted foreground operation command indicates a foreground erase operation on a memory block on which the background erase operation is being performed, the background erase operation processing unit 140 may continue to perform the foreground erase operation on the memory block from a position at which the background erase operation is suspended, based on the background erase status information, without performing the foreground erase operation on the memory block from the start position of the memory block. The background erase operation in accordance with an embodiment of the present disclosure will be described in detail later with reference to FIGS. 5 to 8.

The host 300 may communicate with the storage device 50 using at least one of various communication methods such as Universal Serial Bus (USB), Serial AT Attachment (SATA), Serial Attached SCSI (SAS), High Speed Interchip (HSIC), Small Computer System Interface (SCSI), Peripheral Component Interconnection (PCI), PCI express (PCIe), Nonvolatile Memory express (NVMe), Universal Flash Storage (UFS), Secure Digital (SD), MultiMedia Card (MMC), embedded MMC (eMMC), Dual In-line Memory Module (DIMM), Registered DIMM (RDIMM), and Load Reduced DIMM (LRDIMM) communication methods.

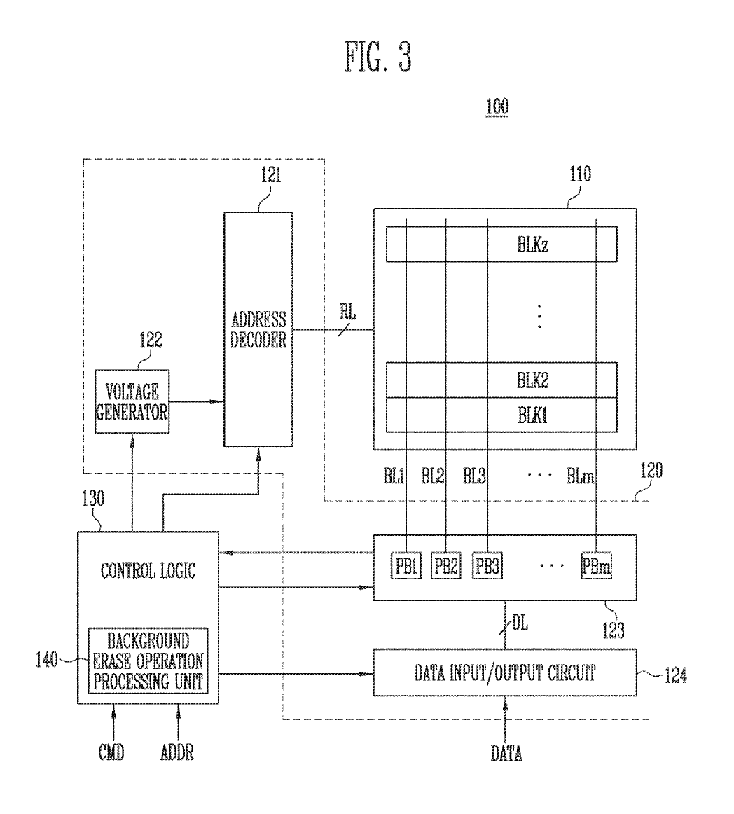

FIG. 2 is a diagram for explaining signals inputted/outputted to/from the memory device 100 of FIG. 1.

Referring to FIG. 2, the memory device 100 may communicate with an external controller through a plurality of input/output lines. For example, the memory device 100 may communicate with the external controller through control signal lines which include a chip enable line CE#, a write enable line WE#, a read enable line RE#, an address latch enable line ALE, a command latch enable line CLE, a write protect line WP#, and a ready/busy line R/B#, and data input/output lines IO0 to IO7.

The memory device 100 may receive a chip enable signal from the external controller through the chip enable line CE#. The memory device 100 may receive a write enable signal from the external controller through the write enable line WE#. The memory device 100 may receive a read enable signal from the external controller through the read enable line RE#. The memory device 100 may receive an address latch enable signal from the external controller through the address latch enable line ALE. The memory device 100 may receive a command latch enable signal from the external controller through the command latch enable line CLE. The memory device 100 may receive a write protect signal from the external controller through the write protect line WP#.

In an embodiment, the memory device 100 may output a ready/busy signal, indicating whether the memory device 100 is in a ready state or in a busy state, to the external controller through the ready/busy line R/B#.

The chip enable signal may be a control signal for selecting the memory device 100. When the chip enable signal is in a ‘high’ state and the memory device 100 is in a ‘ready’ state, the memory device 100 may enter a low-power standby state.

The write enable signal may be a control signal for performing control such that the commands, addresses, and input data which are applied to the memory device are stored in a latch.

The read enable signal may be a control signal for enabling the output of serial data.

The address latch enable signal may be one of control signals used by the host so as to indicate which one of a command, an address, and data corresponds to the type of signal inputted to the input/output lines IO0 to IO7.

The command latch enable signal may be one of control signals used by the host so as to indicate which one of a command, an address, and data corresponds to the type of signal inputted to the input/output lines IO0 to IO7.

For example, when the command latch enable signal is activated (e.g., to a logic high state), the address latch enable signal is deactivated (e.g., to a logic low state), and the write enable signal is activated (e.g., to a logic low state) and then deactivated (e.g., to a logic high state), the memory device 100 may identify whether the signal inputted through the input/output lines IO0 to IO07 is a command.

For example, when the command latch enable signal is deactivated (e.g., to a logic low state), the address latch enable signal is activated (e.g., to a logic high state), and the write enable signal is activated (e.g., to a logic low state) and then deactivated (e.g., to a logic high state), the memory device 100 may identify whether the signal inputted through the input/output lines IO0 to IO07 is an address.

The write protect signal may be a control signal for deactivating the program operation and the erase operation that are performed by the memory device 100.

The ready/busy signal may be a signal for identifying the status of the memory device 100. The ready/busy signal in a low state indicates that the memory device 100 is currently performing at least one operation. The ready/busy signal in a high state indicates that the memory device 100 is not currently performing any operation.

The ready/busy signal may be in a low state while the memory device 100 is performing any one of a program operation, a read operation, and an erase operation as a foreground operation. In an embodiment of the present disclosure, the ready/busy signal may be in a high state while the memory device 100 is performing a background erase operation described above with reference to FIG. 1. Therefore, the memory device 100 may receive a command, an address, and data corresponding to a foreground operation through the input/output lines IO0 to IO7 even while the memory device 100 is performing the background erase operation.

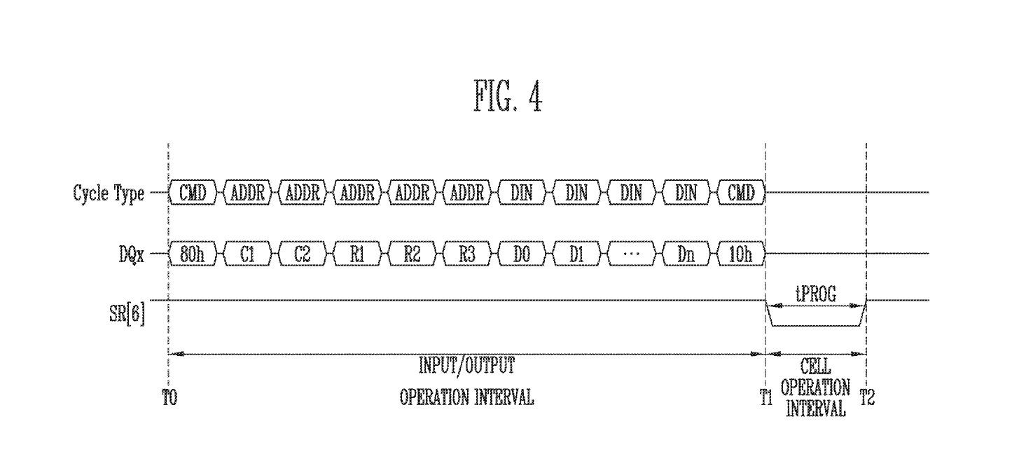

FIG. 3 is a block diagram illustrating the structure of the memory device of FIG. 1.

Referring to FIG. 3, the memory device 100 may include a memory cell array 110, a peripheral circuit 120, and a control logic 130.

The memory cell array 110 includes a plurality of memory blocks BLK1 to BLKz. The plurality of memory blocks BLK1 to BLKz are coupled to an address decoder 121 through row lines RL. The memory blocks BLK1 to BLKz are coupled to a read and write circuit 123 through bit lines BL1 to BLm. Each of the memory blocks BLK1 to BLKz includes a plurality of memory cells. In an embodiment, the plurality of memory cells are nonvolatile memory cells. In the plurality of memory cells, memory cells coupled to the same word line are defined as a single page. That is, the memory cell array 110 is composed of a plurality of pages. In an embodiment, each of the plurality of memory blocks BLK1 to BLKz included in the memory cell array 110 may include a plurality of dummy cells. As the dummy cells, one or more dummy cells may be coupled in series between a drain select transistor and the memory cells and between a source select transistor and the memory cells.

The peripheral circuit 120 may include an address decoder 121, a voltage generator 122, the read and write circuit 123, and a data input/output circuit 124.

The peripheral circuit 120 may drive the memory cell array 110. For example, the peripheral circuit 120 may drive the memory cell array 110 so that a program operation, a read operation, an erase operation, and a background erase operation are performed.

The address decoder 121 is coupled to the memory cell array 110 through row lines RL. The row lines RL may include drain select lines, word lines, source select lines, and a common source line. In an embodiment, the word lines may include normal word lines coupled to memory cells and dummy word lines coupled to the dummy cells. In an embodiment, the row lines RL may further include a pipe select line.

The address decoder 121 is configured to be operated under the control of the control logic 130. The address decoder 121 receives the address ADDR from the control logic 130.

The address decoder 121 is configured to decode a block address of the received address ADDR. The address decoder 121 selects at least one memory block from among the memory blocks BLK1 to BLKz in response to the decoded block address. The address decoder 121 is configured to decode a row address of the received address ADDR. The address decoder 121 may select at least one word line of the selected memory block by applying voltages supplied from the voltage generator 122 to at least one word line WL in response to the decoded row address.

During a program operation, the address decoder 121 may apply a program voltage to the selected word line and apply a pass voltage having a level lower than that of the program voltage to unselected word lines. During a program verify operation, the address decoder 121 may apply a verify voltage to a selected word line and apply a verification pass voltage higher than the verify voltage to unselected word lines.

During a read operation, the address decoder 121 may apply a read voltage to a selected word line and apply a read pass voltage higher than the read voltage to unselected word lines.

In an embodiment, the erase operation of the memory device 100 may be performed on a memory block basis. During an erase operation, the address ADDR input to the memory device 100 includes a block address. The address decoder 121 may decode the block address and select a single memory block in response to the decoded block address. During the erase operation, the address decoder 121 may apply a ground voltage to word lines coupled to the selected memory block.

In an embodiment, the address decoder 121 may be configured to decode a column address of the received address ADDR. A decoded column address may be transferred to the read and write circuit 123. In an exemplary embodiment, the address decoder 121 may include components such as a row decoder, a column decoder, and an address buffer

The voltage generator 122 is configured to generate a plurality of voltages using an external supply voltage provided to the memory device 100. The voltage generator 122 is operated under the control of the control logic 130.

In an embodiment, the voltage generator 122 may generate an internal supply voltage by regulating the external supply voltage. The internal supply voltage generated by the voltage generator 122 is used as an operating voltage of the memory device 100.

In an embodiment, the voltage generator 122 may generate a plurality of voltages using an external supply voltage or an internal supply voltage. The voltage generator 122 may be configured to generate various voltages required by the memory device 100. For example, the voltage generator 122 may generate a plurality of erase voltages, a plurality of program voltages, a plurality of pass voltages, a plurality of select read voltages, and a plurality of unselect read voltages.

The voltage generator 122 may include a plurality of pumping capacitors for receiving the internal supply voltage in order to generate a plurality of voltages having various voltage levels, and may generate a plurality of voltages by selectively activating the pumping capacitors under the control of the control logic 130.

The generated voltages may be supplied to the memory cell array 110 by the address decoder 121.

The read and write circuit 123 includes first to m-th page buffers PB1 to PBm. The first to m-th page buffers PB1 to PBm are coupled to the memory cell array 110 through the first to m-th bit lines BL1 to BLm, respectively. The first to m-th page buffers PB1 to PBm are operated under the control of the control logic 130.

The first to m-th page buffers PB1 to PBm perform data communication with the data input/output circuit 124. During a program operation, the first to m-th page buffers PB1 to PBm receive data to be stored DATA through the data input/output circuit 124 and data lines DL.

During a program operation, the first to m-th page buffers PB1 to PBm may transfer the data DATA, received through the data input/output circuit 124, to selected memory cells through the bit lines BL1 to BLm when a program pulse is applied to each selected word line. The memory cells in the selected page are programmed based on the transferred data DATA. Memory cells coupled to a bit line to which a program permission voltage (e.g. a ground voltage) is applied may have increased threshold voltages. Threshold voltages of memory cells coupled to a bit line to which a program prohibition voltage (e.g. a supply voltage) is applied may be maintained. During a program verify operation, the first to m-th page buffers may read data, in which the threshold voltages of memory cells are stored as verify voltages, from the selected memory cells through the bit lines BL1 to BLm.

During a read operation, the read and write circuit 123 may read data DATA from the memory cells in the selected page through the bit lines BL, and may store the read data DATA in the first to m-th page buffers PB1 to PBm.

During an erase operation, the read and write circuit 123 may allow the bit lines BL to float. In an embodiment, the read and write circuit 123 may include a column select circuit.

The data input/output circuit 124 is coupled to the first to m-th page buffers PB1 to PBm through the data lines DL. The data input/output circuit 124 is operated under the control of the control logic 130.

The data input/output circuit 124 may include a plurality of input/output buffers (not illustrated) for receiving input data. During a program operation, the data input/output circuit 124 receives data to be stored DATA from an external controller (not shown). During a read operation, the data input/output circuit 124 outputs the data, received from the first to m-th page buffers PB1 to PBm included in the read and write circuit 123, to the external controller.

The control logic 130 may be coupled to the address decoder 121, the voltage generator 122, the read and write circuit 123, and the data input/output circuit 124. The control logic 130 may control the overall operation of the memory device 100. The control logic 130 may be operated in response to a command CMD received from an external device.

In an embodiment, the control logic 130 may further include a background erase operation processing unit 140. The background erase operation processing unit 140 may perform a background erase operation. The background erase operation may be performed while the memory device 100 is in an idle state. In the idle state, the memory device 100 performs no foreground operation. In an embodiment, the background erase operation may be performed before the input of a confirm command indicating that the transmission of a foreground operation command and related address and data is completed.

In an embodiment, the foreground operation command may be a foreground command indicative of any one of a program operation, a read operation, and an erase operation as a foreground operation. For example, the foreground operation command may be any one of a program command, a read command, and an erase command.

The background erase operation processing unit 140 may identify whether the command CMD inputted from the memory controller 200 is a background erase command. When the background erase command is inputted, the background erase operation processing unit 140 may perform an erase operation on a memory block in response to the background erase command while the memory device 100 is in an idle state. While the background erase command is executed, the memory device 100 may receive a command CMD, an address ADD, and data DATA for a foreground operation.

When a foreground operation command is inputted while the background erase operation is being performed, the background erase operation processing unit 140 may perform the background erase operation until a confirm command corresponding to the foreground operation command is inputted. When the confirm command is inputted, the background erase operation processing unit 140 may suspend the background erase operation, and may store background erase status information. The background erase status information may indicate the degree to which the background erase operation progresses. For example, the background erase status information may indicate at least one of the number of applications of an erase voltage pulse, the number of performed erase loops, the voltage level of the applied erase voltage pulse, and the erase verification result.

The background erase operation processing unit 140 may suspend the performance of the background erase operation until the foreground operation is completed in response to the foreground operation command. When the foreground operation is completed in response to the foreground operation command, the background erase operation processing unit 140 may resume the suspended background erase operation based on the stored background erase status information. For example, the background erase operation processing unit 140 may resume the background erase operation from the suspended position of the memory block on which the background erase operation was performed at the time of the suspension, without performing the erase operation from the start position of the memory block, depending on the stored background erase status information, i.e., based on at least one of the number of applications of the erase voltage pulse, the number of performed erase loops, the voltage level of the applied erase voltage pulse, and the erase verification result.

In various embodiments, the background erase operation processing unit 140 may determine whether a foreground operation command, which is inputted while the background erase operation is being performed, indicates an erase operation on a memory block on which the background erase operation is being performed. When the inputted foreground operation command indicates a foreground erase operation on a memory block on which the background erase operation is being performed, the background erase operation processing unit 140 may continue to perform the foreground erase operation on the memory block from a position at which the background erase operation is suspended, based on the background erase status information, without performing the foreground erase operation on the memory block from the start position of the memory block. The background erase operation in accordance with an embodiment of the present disclosure will be described in detail later with reference to FIGS. 5 to 8.

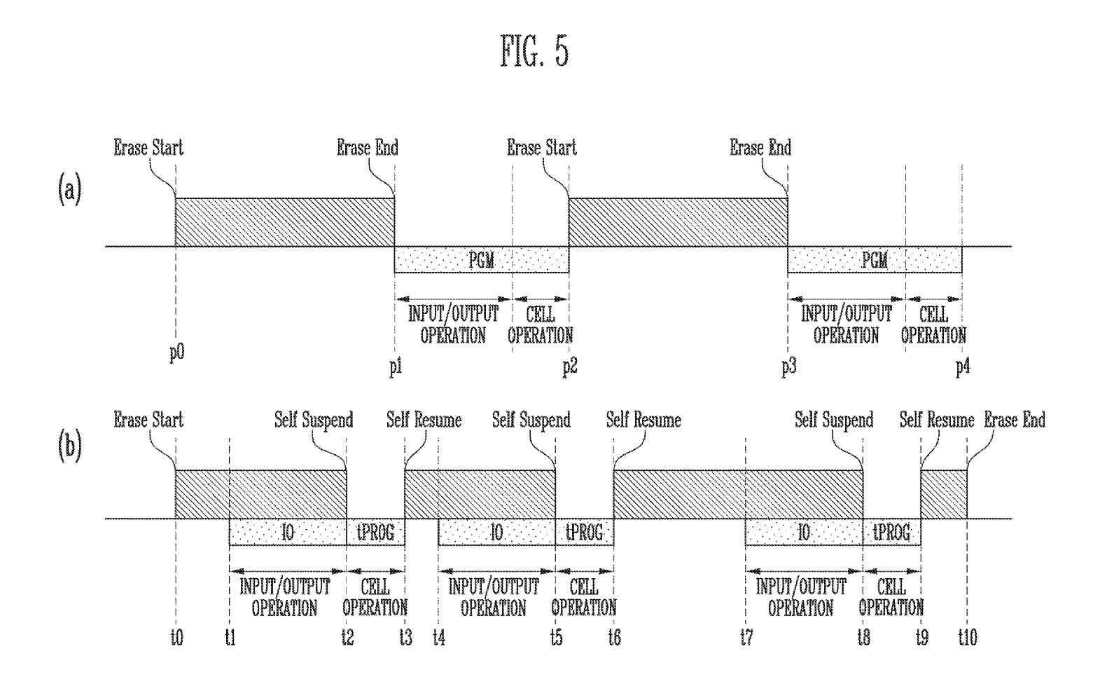

FIG. 4 is a diagram for explaining an input/output operation and a cell operation of a memory device during a program operation.

In an embodiment, the memory device may perform a background erase operation to efficiently perform an erase operation which requires a relatively long time. The memory device may perform a background erase operation to one or more selected memory blocks in response to a background erase command provided by a memory controller.

In an embodiment, the memory device 100 may receive a foreground operation command while the background erase operation is performed. In an embodiment, the foreground operation command may be a program command. In various embodiments, the foreground operation command may be a read command or an erase command.

The foreground operation command may include a first command and a second command. The first command may be a start command indicating which type of operation is the foreground operation, and the second command may be a confirm command indicating that all of addresses and data required to execute the first command have been inputted. When the first command of the foreground operation command is inputted while the background erase operation is being performed, the memory device may continue to perform the background erase operation until the confirm command, i.e., the second command of the foreground operation command is inputted.

Below, a case where a foreground operation command is a program command will be described by way of example. However, the embodiment of the present disclosure is not limited to the case where the foreground operation command is a program command.

Referring to FIG. 4 “DQx” denotes signals inputted through input/output lines IO0 to IO7, as described above with reference to FIG. 2, and “Cycle Type” denotes the type of corresponding signals. “SR[6]” denotes a ready/busy signal outputted through a ready/busy line R/B#, as described above with reference to FIG. 2. In an embodiment, the ready/busy signal SR[6] may indicate the value of a status register included in the memory device 100. The status register may store status information indicating whether execution of the foreground operation command or the background erase command received by the memory device 100 has been completed.

During a period from T0 to T1, the memory device 100 may receive foreground program commands, addresses, and data.

The foreground program command may be the first command for the foreground program operation. For example, the foreground program command may be a start command for the foreground program operation.

During a period from T1 to T2, the memory device 100 may perform a foreground program operation of programming data to an area corresponding to the received addresses. In detail, the memory device may receive 80h indicating a foreground program command CMD at time T0. The memory device may receive the addresses ADDR during the subsequent five cycles. The received addresses ADDR may include column addresses C1 and C2 and row addresses R1, R2, and R3.

Thereafter, the memory device may receive data to be programmed, that is, pieces of program data D0 to Dn. After the pieces of program data D0 to Dn have been inputted, the memory device may receive a second command 10h. The second command 10h may be a confirm command indicating that all addresses and data relating to the foreground program command CMD 80h which is the first command have been inputted.

When the second command 10h is inputted, the memory device may perform a foreground program operation of storing the inputted program data D0 to Dn in an area corresponding to the inputted addresses ADDR. The memory device may perform the foreground program operation during the period from T1 to T2 corresponding to tPROG.

Therefore, the memory device may perform an input/output operation which receives the commands CMD, the addresses ADDR, and the data D0 to D7 required for the foreground program operation through the input/output lines IO0 to IO7 during the period from T0 to T1, and may perform a foreground program operation of storing the program data D0 to Dn at the addresses ADDR during the period from T1 to T2 which is a period after the confirm command has been inputted.

That is, during the period from T0 to T1, the memory device 100 merely receives the commands CMD, the addresses ADDR, and the data D0 to Dn which are required for the foreground program operation through the input/output lines IO0 to IO7, but does not perform the foreground program operation of actually storing data in memory cells. Therefore, while the input/output operation corresponding to the period from T0 to T1 is being performed, another operation may be performed on the memory cells.

FIG. 5 is a diagram for explaining a background erase operation in accordance with an embodiment of the present disclosure.

In FIG. 5, (a) is a diagram for explaining a case where a foreground program command is inputted while a foreground erase operation is being performed, and (b) is a diagram for explaining a case where a foreground program command is inputted while a background erase operation is being performed in accordance with an embodiment of the present disclosure.

Referring to FIG. 5(a), the foreground erase operation may be performed during a period from p0 to p1. Here, p0 (also denoted with “Erase Start”) is a time at which the erase operation starts, and p1 (also denoted with “Erase End”) is a time at which the erase operation ends. During the period from p0 to p1, a busy signal may be outputted through the ready/busy line of the memory device. Therefore, the memory device may not receive a foreground program command which is a subsequent command. After the foreground erase operation has ended, the memory device may receive a foreground program command for instructing the performance of a foreground program operation, addresses, and data from a memory controller, and may perform the foreground program operation of storing the received data at selected addresses.

A period from p1 to p2 during which the foreground program operation is performed may be divided into an input/output operation interval in which the memory device receives a first command, addresses, data, and a second command, and a cell operation interval in which the received data is stored in memory cells selected by the addresses. In an embodiment, the first command may be a start command indicating that the received command is a foreground program operation command. For example, the start command may be a foreground program command. In an embodiment, the second command may be a confirm command indicating that the input of addresses and data required to execute the first command has been completed.

During a period from p2 to p3, a foreground erase operation may be performed. Here, p2 (also denoted with “Erase Start”) is a time at which the foreground erase operation starts, and p3 (also denoted with “Erase End”) is a time at which the foreground erase operation ends. During the period from p2 to p3, a busy signal may be outputted through the ready/busy line of the memory device. Therefore, the memory device may not receive a program command which is a subsequent command. After the foreground erase operation has ended, the memory device may receive a foreground program command for instructing the performance of a foreground program operation, addresses, and data from a memory controller, and may perform the foreground program operation of storing the received data at a selected address.

A period from p3 to p4 during which the foreground program operation is performed may be divided into an input/output operation interval in which the memory device receives a first command, addresses, data, and a second command, and a cell operation interval in which the received data is stored in memory cells selected by the addresses. In an embodiment, the first command may be a start command indicating that the received command is a foreground program operation command. For example, the start command may be a foreground program command. In an embodiment, the second command may be a confirm command indicating that the input of addresses and data required to execute the first command has been completed.

In (a), the memory device cannot receive a command corresponding to a subsequent foreground operation while the foreground erase operation is being performed, and thus the memory device may perform the subsequent foreground operation only after the foreground erase operation has been completed even if an I/O data path other than a memory cell area is not actually driven.

Referring to FIG. 5(b), t0 (also denoted with “Erase Start”) is a time at which a background erase operation starts. While the background erase operation is being performed, the memory device 100 may receive a foreground operation command from the memory controller 200.

At time t1, the memory device 100 may receive a command related to the foreground program operation. In detail, the memory device 100 may receive a first command, addresses, data, and a second command during a period from t1 to t2. In an embodiment, the first command may be a start command indicating a foreground program operation. The second command may be a confirm command indicating that the input of addresses and data required to execute the first command has been completed.

In an embodiment, the background erase operation may be a self-suspend operation. When the confirm command is inputted at time t2, the memory device 100 may autonomously suspend the background erase operation, which is being performed, even if a separate suspend command is not received. That is, when the confirm command for the foreground operation command is inputted, the memory device 100 may suspend the background erase operation, which is being performed, in response to the inputted confirm command. The memory device 100 may suspend the background erase operation, and may store background erase status information. In an embodiment, the background erase status information may indicate the degree of progress of the background erase operation. For example, the background erase status information may indicate at least one of the number of applications of an erase voltage pulse, the number of performed erase loops, the voltage level of the applied erase voltage pulse, and the erase verification result.

During a period from t2 to t3, the memory device 100 may perform a foreground program operation in response to the foreground program command which is inputted during the period from t1 to t2.

When the foreground program operation is completed at time t3, the memory device 100 may resume the background erase operation, which was suspended at time t2. In an embodiment, the background erase operation may be a self-resume operation. Even if an operation resume command CMD is not received from the memory controller 200, the memory device 100 may autonomously resume the background erase operation in response to a status information value, indicating the completion of the foreground program operation. When resuming the background erase operation, the memory device 100 may resume the background erase operation based on the background erase status information stored at time t2. For example, the memory device 100 may continue to perform the background erase operation based on at least one of the number of applications of an erase voltage pulse, the number of erase loops that are executed, the level of the applied erase voltage, and the erase verification result, which were present at the suspend time t2.

At time t4, the memory device 100 may receive a command related to the foreground program operation. In detail, the memory device 100 may receive a first command, addresses, data, and a second command during a period from t4 to t5. In an embodiment, the first command may be a start command indicating a foreground program operation. The second command may be a confirm command indicating that the input of addresses and data required to execute the first command has been completed.

As described above, the background erase operation may be a self-suspend operation. When the confirm command is inputted at time t5, the memory device 100 may autonomously suspend again the background erase operation, which is being performed, even if a separate suspend command is not received. That is, when the confirm command for the foreground operation command is inputted, the memory device 100 may suspend the background erase operation, which is being performed, in response to the inputted confirm command. The memory device 100 may suspend the background erase operation, and may store background erase status information. In an embodiment, the background erase status information may indicate the degree to which the background erase operation progresses. For example, the background erase status information may indicate at least one of the number of applications of an erase voltage pulse, the number of performed erase loops, the voltage level of the applied erase voltage pulse, and the erase verification result.

During a period from t5 to t6, the memory device 100 may perform a foreground program operation in response to the foreground program command which is inputted during the period from t4 to t5.

When the foreground program operation is completed at time t6, the memory device 100 may resume the background erase operation, which was suspended at time t5. As described above, the background erase operation may be a self-resume operation. Even if an operation resume command CMD is not received from the memory controller 200, the memory device 100 may autonomously resume the background erase operation in response to a status information value, indicating the completion of the program operation. When resuming the background erase operation, the memory device 100 may resume the background erase operation based on the background erase status information stored at time t5. For example, the memory device 100 may continue to perform the background erase operation based on at least one of the number of applications of an erase voltage pulse, the number of erase loops that are executed, the level of the applied erase voltage, and the erase verification result, which were present at the suspend time t5.

At time t7, the memory device 100 may receive a command related to the foreground program operation. In detail, the memory device 100 may receive a first command, addresses, data, and a second command during a period from t7 to t8. In an embodiment, the first command may be a start command indicating a foreground program operation. The second command may be a confirm command indicating that the input of addresses and data required to execute the first command has been completed.

As described above, the background erase operation may be a self-suspend operation. When the confirm command is inputted at time t8, the memory device 100 may autonomously suspend again the background erase operation, which is being performed, even if a separate suspend command is not received. That is, when the confirm command for the foreground operation command is inputted, the memory device 100 may suspend the background erase operation, which is being performed, in response to the inputted confirm command. The memory device 100 may suspend the background erase operation, and may store background erase status information. In an embodiment, the background erase status information may indicate the degree to which the background erase operation progresses. For example, the background erase status information may indicate at least one of the number of applications of an erase voltage pulse, the number of performed erase loops, the voltage level of the applied erase voltage pulse, and the erase verification result.

During a period from t8 to t9, the memory device 100 may perform a foreground program operation in response to the foreground program command which is inputted during the period from t7 to t8.

When the foreground program operation is completed at time t9, the memory device 100 may resume the background erase operation, which was suspended at time t8. As described above, the background erase operation may be a self-resume operation. Even if an operation resume command CMD is not received from the memory controller 200, the memory device 100 may autonomously resume the background erase operation in response to a status information value, indicating the completion of the program operation. When resuming the background erase operation, the memory device 100 may resume the background erase operation based on the background erase status information stored at time t8. For example, the memory device 100 may continue to perform the background erase operation based on at least one of the number of applications of an erase voltage pulse, the number of erase loops that are executed, the level of the applied erase voltage, and the erase verification result, which were present at the suspend time t8.

At time t10 (also denoted with “Erase End”), the background erase operation, which is being performed by the memory device 100, may be terminated.

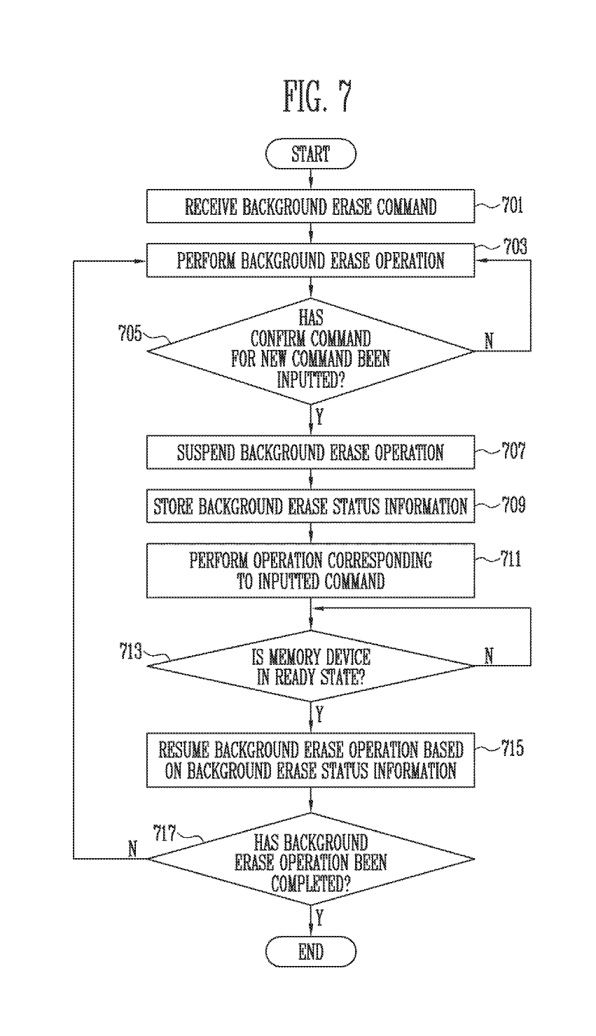

FIG. 6 is a diagram illustrating the structure of the background erase operation processing unit 140 of FIG. 3.

Referring to FIG. 6, the background erase operation processing unit 140 may include a command register 141, a status register 142, a background erase operation control unit 143, and a background erase status register 144.

The command register 141 may receive commands CMD from an external controller. When a command CMD received from the external controller 200 is a background erase command, the command register 141 may enable a background erase trigger signal BKOP ERASE TRIG which is outputted to the background erase operation control unit 143. In an embodiment, when a confirm command for a foreground operation is inputted from the external controller while the background erase trigger signal BKOP ERASE TRIG is enabled, the command register 141 may disable the background erase trigger signal BKOP ERASE TRIG.

The status register 142 may receive status information STATUS INFO depending on the operating status of a memory cell array 110, described above with reference to FIG. 3. The status information STATUS INFO may indicate the operating status of the memory device 100. For example, the status information STATUS INFO may indicate whether the execution of the most recently received command has failed. Alternatively, in an embodiment, the status information STATUS INFO may indicate whether the execution of a command, received prior to the most recently received command, has failed. Alternatively, in an embodiment, the status information STATUS INFO may indicate whether there is a cell operation in progress. Alternatively, in an embodiment, the status information STATUS INFO may indicate whether the memory device 100 is currently available for a new operation. In an embodiment, the memory device 100 may output a ready signal or a busy signal through a ready/busy line R/B#, described above with reference to FIG. 2, based on the status information STATUS INFO stored in the status register 142.

When the background erase operation is completed, the status register 142 may receive a status value STATUS VALUE, which indicates that the background erase operation has been completed, from the background erase operation control unit 143. Alternatively, in an embodiment, the status register 142 may provide the background erase operation control unit 143 with a status register value stored therein as a status value STATUS VALUE.

The background erase operation control unit 143 may receive the background erase trigger signal BKOP ERASE TRIG from the command register 141. When the background erase trigger signal BKOP ERASE TRIG is in an enabled state, the background erase operation control unit 143 may output a control signal CTRL for controlling the peripheral circuit 120 so that the background erase operation is performed. In an embodiment, when the background erase trigger signal BKOP ERASE TRIG changes from the enabled state to a disabled state, the background erase operation control unit 143 may output a control signal CTRL for controlling the peripheral circuit 120 so that the background erase operation is suspended.

When the background erase trigger signal BKOP ERASE TRIG changes from the enabled state to the disabled state, the background erase operation control unit 143 may provide the background erase status register 144 with background erase status information ERASE STATUS, which is information about the progress of the background erase operation performed to that time. In an embodiment, the background erase status information ERASE STATUS may indicate the degree to which the background erase operation progresses. For example, the background erase status information ERASE STATUS may indicate at least one of the number of applications of an erase voltage pulse, the number of performed erase loops, the voltage level of the applied erase voltage pulse, and the erase verification result.

When the background erase trigger signal BKOP ERASE TRIG changes from the disabled state to the enabled state, the background erase operation control unit 143 may resume the background erase operation. When resuming the background erase operation, the background erase operation control unit 143 may refer to the background erase status information ERASE STATUS stored in the background erase status register 144. For example, the background erase operation control unit 143 may continue to perform an erase operation from the suspended position of the erase operation at a time at which the background erase operation was previously suspended. For example, the background erase operation processing unit 140 may resume the background erase operation from the suspended position of the memory block on which the background erase operation was performed at the time of the suspension, without performing the erase operation from the start position of the memory block, depending on at least one of the number of applications of the erase voltage pulse, the number of performed erase loops, the voltage level of the applied erase voltage pulse, and the erase verification result.

In an embodiment, among foreground operation commands, a foreground erase command may be inputted for a particular memory block while the background erase operation is being performed on that particular memory block.

In this case, the background erase operation control unit 143 may perform the background erase operation on the corresponding memory block as a foreground erase operation without suspending the background erase operation. For example, the background erase operation control unit 143 may not suspend the background erase operation when an address at which the foreground erase command is to be executed is identical to an address at which the background erase operation is being performed.

Alternatively, in various embodiments, when a confirm command corresponding to the foreground erase command is inputted, the background erase operation control unit 143 may output a control signal CTRL for suspending the background erase operation, and may store background erase status information ERASE STATUS at a suspend time. Thereafter, when the address at which the foreground erase command is to be executed is identical to the address at which the background erase operation is being performed, the foreground erase operation may be performed from the suspended position of the memory block on which the background erase operation was performed at the time of the suspension, without performing the foreground erase operation from the start position of the memory block, depending on the stored background erase status information ERASE STATUS.

In an embodiment, the background erase operation processing unit 140 may be included in the control logic 130, described above with reference to FIG. 3, or may be implemented as a logic circuit provided separately from the control logic 130.

In various embodiments, the command register 141 and the status register 142 may not be included in the background erase operation processing unit 140.

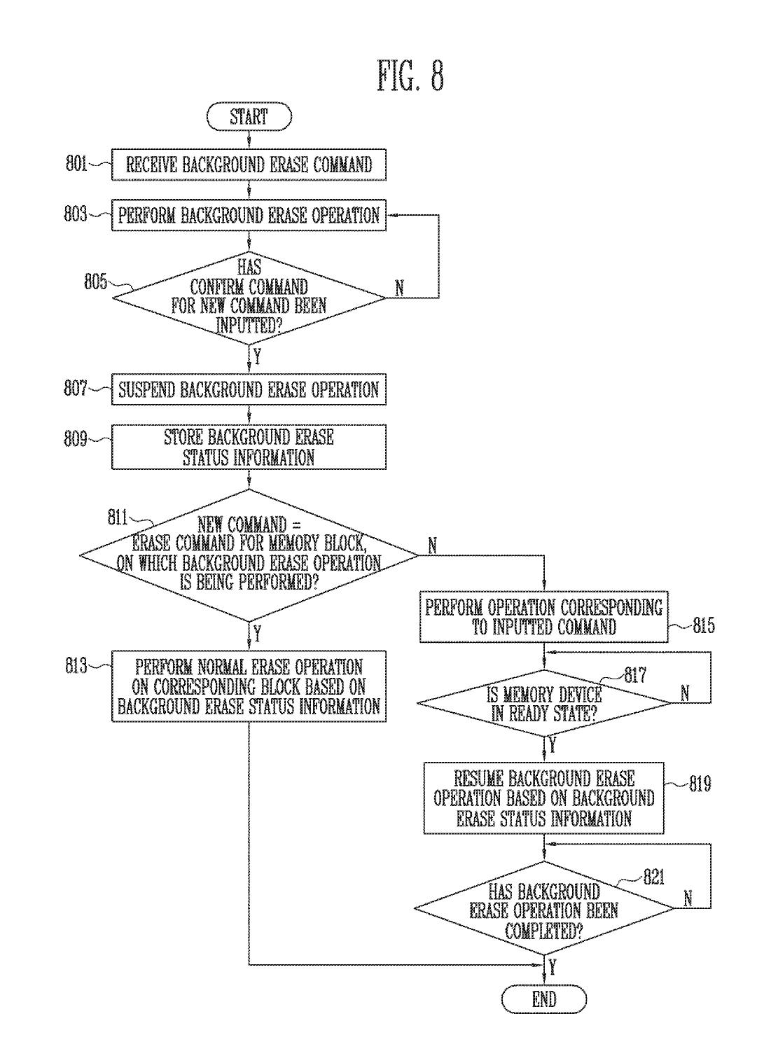

FIG. 7 is a flowchart illustrating the operation of the memory device 100 in accordance with an embodiment of the present disclosure.

Referring to FIG. 7, the memory device 100 may receive a background erase command at step 701.

At step 703, the memory device 100 may perform a background erase operation. While the background erase operation is being performed, status information STATUS INFO stored in the status register 142 of the memory device 100 may indicate that there is no cell operation in progress. Alternatively, the status information STATUS INFO may indicate that the memory device 100 is available for a new foreground operation. Therefore, depending on the status value STATUS VALUE of the status register 142, a ready signal may be outputted through the ready/busy line of the memory device 100.

At step 705, the memory device 100 may determine whether a confirm command for a new foreground command has been inputted. When it is determined that the confirm command for the new foreground command has been inputted, the memory device 100 proceeds to step 707. Otherwise the memory device 100 returns to step 703 where the background erase operation may continue to be performed.

At step 707, the memory device 100 may suspend the ongoing background erase operation.

At step 709, the memory device 100 may store background erase status information ERASE STATUS in the background erase status register 144. In an embodiment, the background erase status information ERASE STATUS may indicate the degree to which the background erase operation progresses. For example, the background erase status information ERASE STATUS may indicate at least one of the number of applications of an erase voltage pulse, the number of performed erase loops, the voltage level of the applied erase voltage pulse, and the erase verification result.

At step 711, the memory device 100 may perform a foreground operation corresponding to the inputted foreground command. When the performance of the foreground operation corresponding to the inputted foreground command is completed, the status register 142 included in the memory device 100 may store status information STATUS INFO indicating that the memory device 100 is in a ready state.

At step 713, the memory device 100 may determine whether the memory device 100 is in a ready state, based on the status value STATUS VALUE of the status register 142. When it is determined that the memory device 100 is in the ready state, the memory device 100 proceeds to step 715, otherwise the memory device 100 returns to step 713.

At step 715, the memory device 100 may resume the suspended background erase operation based on the background erase status information ERASE STATUS, which is stored in the background erase status register 144 at step 709.

At step 717, the memory device 100 may determine whether the resumed background erase operation has been completed.

FIG. 8 is a flowchart illustrating the operation of the memory device 100 in accordance with an embodiment of the present disclosure.

Referring to FIG. 8, the memory device 100 may receive a background erase command at step 801.

At step 803, the memory device 100 may perform a background erase operation. While the background erase operation is being performed, status information STATUS INFO stored in the status register 142 of the memory device 100 may indicate that there is no cell operation in progress. Alternatively, the status information STATUS INFO may indicate that the memory device 100 is available for performing a new foreground operation. Therefore, depending on the status value STATUS VALUE of the status register 142, a ready signal may be outputted through the ready/busy line of the memory device 100.

At step 805, the memory device 100 may determine whether a confirm command for a new foreground command has been inputted. When it is determined that the confirm command for the new foreground command has been inputted, the memory device 100 proceeds to step 807. Otherwise the memory device 100 returns to step 803 where the background erase operation may continue to be performed.

At step 807, the memory device 100 may suspend the ongoing background erase operation.

At step 809, the memory device 100 may store background erase status information ERASE STATUS in the background erase status register 144. In an embodiment, the background erase status information ERASE STATUS may indicate the degree to which the background erase operation progresses. For example, the background erase status information ERASE STATUS may indicate at least one of the number of applications of an erase voltage pulse, the number of performed erase loops, the voltage level of the applied erase voltage pulse, and the erase verification result.

At step 811, the memory device 100 may determine whether the new foreground command is a foreground erase command for a memory block on which the suspended background erase operation was being performed.

In an embodiment, unlike the configuration illustrated in the drawing, the memory device 100 may not suspend the background erase operation when an address at which the foreground erase command is to be executed is identical to an address at which the background erase operation is being performed.

Alternatively, in various embodiments, when the address at which the foreground erase command is to be executed is identical to the address at which the background erase operation is being performed, the memory device 100 may proceed to step 813, otherwise the memory device 100 may proceed to 815.

At step 813, the memory device 100 may perform the erase operation from the suspended position of the memory block on which the background erase operation was performed at the time of the suspension, without performing the foreground erase operation from the start position of the memory block, depending on the stored background erase status information ERASE STATUS at the time of the suspension.

At step 815, the memory device 100 may perform a foreground operation corresponding to the inputted foreground command. When the performance of the foreground operation corresponding to the inputted foreground command is completed, the status register 142 included in the memory device 100 may store status information STATUS INFO indicating that the memory device 100 is in a ready state.

At step 817, the memory device 100 may determine whether the memory device 100 is in a ready state, based on the status value STATUS VALUE of the status register 142. When it is determined that the memory device 100 is in the ready state, the memory device 100 proceeds to step 819, otherwise the memory device 100 returns to step 817.

At step 819, the memory device 100 may resume the suspended background erase operation based on the background erase status information ERASE STATUS, which is stored in the background erase status register 144 at step 809.

At step 821, the memory device 100 may determine whether the resumed background erase operation has been completed, and may terminate the background erase operation based on the result of determination.

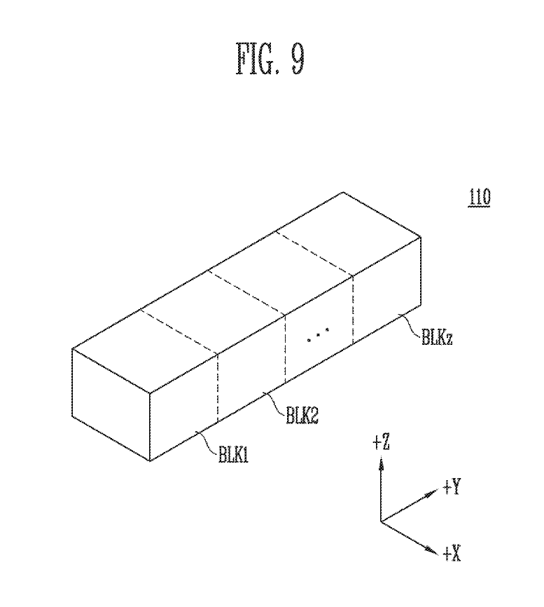

FIG. 9 is a diagram illustrating an embodiment of the memory cell array of FIG. 3.

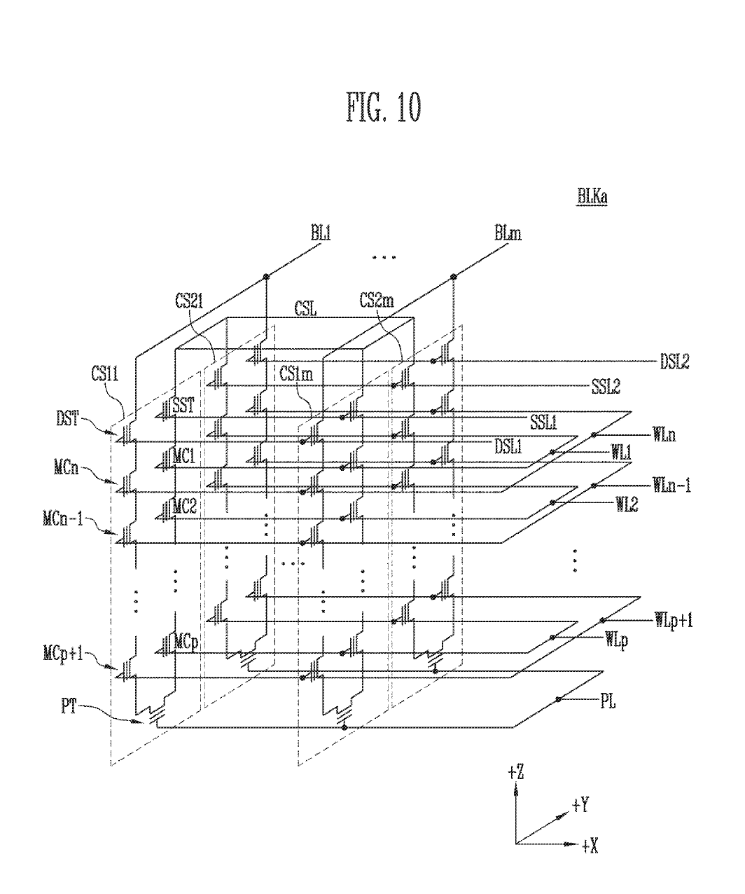

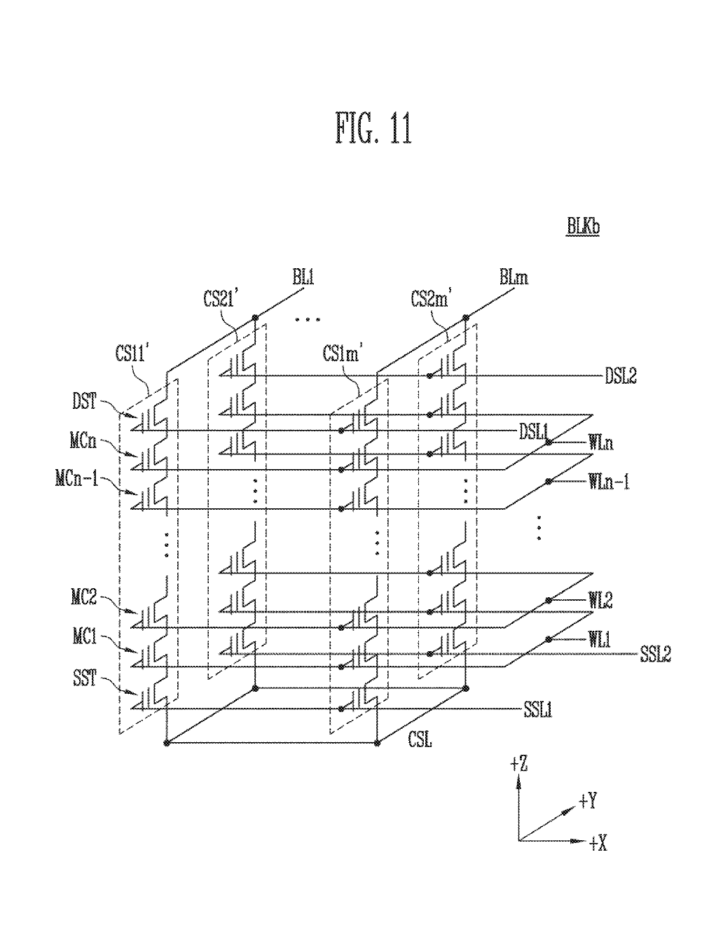

Referring to FIG. 9, the memory cell array 110 includes a plurality of memory blocks BLK1 to BLKz. Each memory block has a three-dimensional (3D) structure. Each memory block includes a plurality of memory cells stacked on a substrate. Such memory cells are arranged along a positive X (+X) direction, a positive Y (+Y) direction, and a positive Z (+Z) direction. The structure of each memory block will be described in detail below with reference to FIGS. 10 and 11.

FIG. 10 is a circuit diagram illustrating any one memory block BLKa of the memory blocks BLK1 to BLKz of FIG. 9.

Referring to FIG. 10, the memory block BLKa includes a plurality of cell strings CS11 to CS1m and CS21 to CS2m. In an embodiment, each of the cell strings CS11 to CS1m and CS21 to CS2m may be formed in a ‘U’ shape. In the memory block BLKa, m cell strings are arranged in a row direction (i.e. a positive (+) X direction). In FIG. 10, two cell strings are shown as being arranged in a column direction (i.e. a positive (+) Y direction). However, this illustration is made for convenience of description, and it will be understood that three or more cell strings may be arranged in the column direction.

Each of the plurality of cell strings CS11 to CS1m and CS21 to CS2m includes at least one source select transistor SST, first to n-th memory cells MC1 to MCn, a pipe transistor PT, and at least one drain select transistor DST.

The select transistors SST and DST and the memory cells MC1 to MCn may have similar structures, respectively. In an embodiment, each of the select transistors SST and DST and the memory cells MC1 to MCn may include a channel layer, a tunneling insulating layer, a charge storage layer, and a blocking insulating layer. In an embodiment, a pillar for providing the channel layer may be provided to each cell string. In an embodiment, a pillar for providing at least one of the channel layer, the tunneling insulating layer, the charge storage layer, and the blocking insulating layer may be provided to each cell string.

The source select transistor SST of each cell string is connected between the common source line CSL and memory cells MC1 to MCp.

In an embodiment, the source select transistors of cell strings arranged in the same row are coupled to a source select line extended in a row direction, and source select transistors of cell strings arranged in different rows are coupled to different source select lines. In FIG. 10, source select transistors of cell strings CS11 to CS1m in a first row are coupled to a first source select line SSL1. The source select transistors of cell strings CS21 to CS2m in a second row are coupled to a second source select line SSL2.

In an embodiment, source select transistors of the cell strings CS11 to CS1m and CS21 to CS2m may be coupled in common to a single source select line.

The first to nth memory cells MC1 to MCn in each cell string are coupled between the source select transistor SST and the drain select transistor DST.

The first to n-th memory cells MC1 to MCn may be divided into first to p-th memory cells MC1 to MCp and p+1-th to n-th memory cells MCp+1 to MCn. The first to p-th memory cells MC1 to MCp are sequentially arranged in a direction opposite a positive (+) Z direction and are connected in series between the source select transistor SST and the pipe transistor PT. The p+1-th to n-th memory cells MCp+1 to MCn are sequentially arranged in the +Z direction and are connected in series between the pipe transistor PT and the drain select transistor DST. The first to p-th memory cells MC1 to MCp and the p+1-th to n-th memory cells MCp+1 to MCn are coupled to each other through the pipe transistor PT. The gates of the first to n-th memory cells MC1 to MCn of each cell string are coupled to first to n-th word lines WL1 to WLn, respectively.

The gate of the pipe transistor PT of each cell string is coupled to a pipeline PL.

The drain select transistor DST of each cell string is connected between the corresponding bit line and the memory cells MCp+1 to MCn. The cell strings in a row direction are coupled to drain select lines extended in a row direction. Drain select transistors of cell strings CS11 to CS1m in the first row are coupled to a first drain select line DSL1. Drain select transistors of cell strings CS21 to CS2m in a second row are coupled to a second drain select line DSL2.

Cell strings arranged in a column direction are coupled to bit lines extended in a column direction. In FIG. 10, cell strings CS11 and CS21 in a first column are coupled to a first bit line BL1. Cell strings CS1m and CS2m in an m-th column are coupled to an m-th bit line BLm.

The memory cells coupled to the same word line in cell strings arranged in a row direction constitute a single page. For example, memory cells coupled to the first word line WL1, among the cell strings CS11 to CS1m in the first row, constitute a single page. Memory cells coupled to the first word line WL1, among the cell strings CS21 to CS2m in the second row, constitute a single additional page. Cell strings arranged in the direction of a single row may be selected by selecting any one of the drain select lines DSL1 and DSL2. A single page may be selected from the selected cell strings by selecting any one of the word lines WL1 to WLn.

In an embodiment, even bit lines and odd bit lines, instead of first to m-th bit lines BL1 to BLm, may be provided. Further, even-numbered cell strings, among the cell strings CS11 to CS1m or CS21 to CS2m arranged in a row direction, may be coupled to the even bit lines, respectively, and odd-numbered cell strings, among the cell strings CS11 to CS1m or CS21 to CS2m arranged in the row direction, may be coupled to the odd bit lines, respectively.

In an embodiment, one or more of the first to n-th memory cells MC1 to MCn may be used as dummy memory cells. For example, one or more dummy memory cells are provided to reduce an electric field between the source select transistor SST and the memory cells MC1 to MCp. Alternatively, the one or more dummy memory cells are provided to reduce an electric field between the drain select transistor DST and the memory cells MCp+1 to MCn. As more dummy memory cells are provided, the reliability of the operation of the memory block BLKa is improved, but the size of the memory block BLKa is increased. As fewer memory cells are provided, the size of the memory block BLKa is reduced, but the reliability of the operation of the memory block BLKa may be deteriorated.

In order to efficiently control the one or more dummy memory cells, each of the dummy memory cells may have a required threshold voltage. Before or after the erase operation of the memory block BLKa is performed, a program operation may be performed on all or some of the dummy memory cells. When an erase operation is performed after the program operation has been performed, the threshold voltages of the dummy memory cells control the voltages that are applied to the dummy word lines coupled to respective dummy memory cells, and thus the dummy memory cells may have required threshold voltages.

FIG. 11 is a circuit diagram illustrating an example of any one memory block BLKb of the memory blocks BLK1 to BLKz of FIG. 9.

Referring to FIG. 11, the memory block BLKb includes a plurality of cell strings CS11′ to CS1m′ and CS21′ to CS2m′. Each of the plurality of cell strings CS11′ to CS1m′ and CS21′ to CS2m′ is extended along a positive Z (+Z) direction. Each of the cell strings CS11′ to CS1m′ and CS21′ to CS2m′ includes at least one source select transistor SST, first to nth memory cells MC1 to MCn, and at least one drain select transistor DST, which are stacked on a substrate (not illustrated) below the memory block BLKb.

The source select transistor SST of each cell string is connected between a common source line CSL and memory cells MC1 to MCn. The source select transistors of cell strings arranged in the same row are coupled to the same source select line. Source select transistors of cell strings CS11′ to CS1m′ arranged in a first row are coupled to a first source select line SSL1. Source select transistors of cell strings CS21′ to CS2m′ arranged in a second row are coupled to a second source select line SSL2. In an embodiment, source select transistors of the cell strings CS11′ to CS1m′ and CS21′ to CS2m′ may be coupled in common to a single source select line.

The first to n-th memory cells MC1 to MCn in each cell string are connected in series between the source select transistor SST and the drain select transistor DST. The gates of the first to nth memory cells MC1 to MCn are coupled to first to nth word lines WL1 to WLn, respectively.

The drain select transistor DST of each cell string is connected between the corresponding bit line and the memory cells MC1 to MCn. Drain select transistors of cell strings arranged in a row direction are coupled to drain select lines extended in a row direction. The drain select transistors of the cell strings CS11′ to CS1m′ in the first row are coupled to a first drain select line DSL1. The drain select transistors of the cell strings CS21′ to CS2m′ in the second row are coupled to a second drain select line DSL2.

As a result, the memory block BLKb of FIG. 11 has an equivalent circuit similar to that of the memory block BLKa of FIG. 10 except that a pipe transistor PT is excluded from each cell string.

In an embodiment, even bit lines and odd bit lines, instead of first to m-th bit lines BL1 to BLm, may be provided. Further, even-numbered cell strings, among the cell strings CS11′ to CS1m′ or CS21′ to CS2m′ arranged in a row direction, may be coupled to the even bit lines, respectively, and odd-numbered cell strings, among the cell strings CS11′ to CS1m′ or CS21′ to CS2m′ arranged in the row direction, may be coupled to the odd bit lines, respectively.

In an embodiment, one or more of the first to n-th memory cells MC1 to MCn may be used as dummy memory cells. For example, the one or more dummy memory cells are provided to reduce an electric field between the source select transistor SST and the memory cells MC1 to MCn. Alternatively, the one or more dummy memory cells are provided to reduce an electric field between the drain select transistor DST and the memory cells MC1 to MCn. As more dummy memory cells are provided, the reliability of the operation of the memory block BLKb is improved, but the size of the memory block BLKb is increased. As fewer memory cells are provided, the size of the memory block BLKb is reduced, but the reliability of the operation of the memory block BLKb may be deteriorated.

In order to efficiently control the one or more dummy memory cells, each of the dummy memory cells may have a required threshold voltage. Before or after the erase operation of the memory block BLKb is performed, a program operation may be performed on all or some of the dummy memory cells. When an erase operation is performed after the program operation has been performed, the threshold voltages of the dummy memory cells control the voltages that are applied to the dummy word lines coupled to respective dummy memory cells, and thus the dummy memory cells may have required threshold voltages.

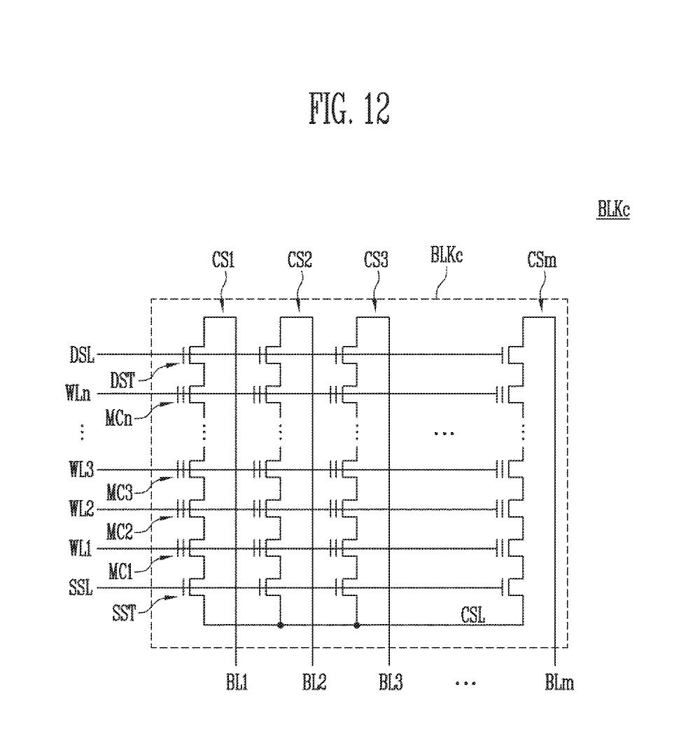

FIG. 12 is a circuit diagram illustrating an embodiment of the memory cell array of FIG. 3.

Referring to FIG. 12, the memory cell array may have a two-dimensional (2D) planar structure, not the 3D structure described above with reference to FIGS. 9 to 11.

In FIG. 12, a memory block BLKc includes a plurality of cell strings CS1 to CSm. The plurality of cell strings CS1 to CSm may be coupled to a plurality of bit lines BL1 to BLm, respectively. Each of the cell strings CS1 to CSm includes at least one source select transistor SST, first to n-th memory cells MC1 to MCn, and at least one drain select transistor DST.

The select transistors SST and DST and the memory cells MC1 to MCn may have similar structures. In an embodiment, each of the select transistors SST and DST and the memory cells MC1 to MCn may include a channel layer, a tunneling insulating layer, a charge storage layer, and a blocking insulating layer. In an embodiment, a pillar for providing the channel layer may be provided in each cell string. In an embodiment, a pillar for providing at least one of the channel layer, the tunneling insulating layer, the charge storage layer, and the blocking insulating layer may be provided in each cell string.

The source select transistor SST of each cell string is coupled between a common source line CSL and the memory cells MC1 to MCn.

The first to n-th memory cells MC1 to MCn in each cell string are coupled between the source select transistor SST and the drain select transistor DST.

The drain select transistor DST of each cell string is coupled between the corresponding bit line and the memory cells MC1 to MCn.

The memory cells coupled to the same word line may constitute a single page. The cell strings CS1 to CSm may be selected by selecting the drain select line DSL. One page may be selected from the selected cell strings by selecting any one of the word lines WL1 to WLn.

In other embodiments, even bit lines and odd bit lines may be provided instead of the first to m-th bit lines BL1 to BLm. Among the cell strings CS1 to CSm, even-numbered cell strings may be coupled to the even bit lines, respectively, and odd-numbered cell strings may be coupled to the odd bit lines, respectively.

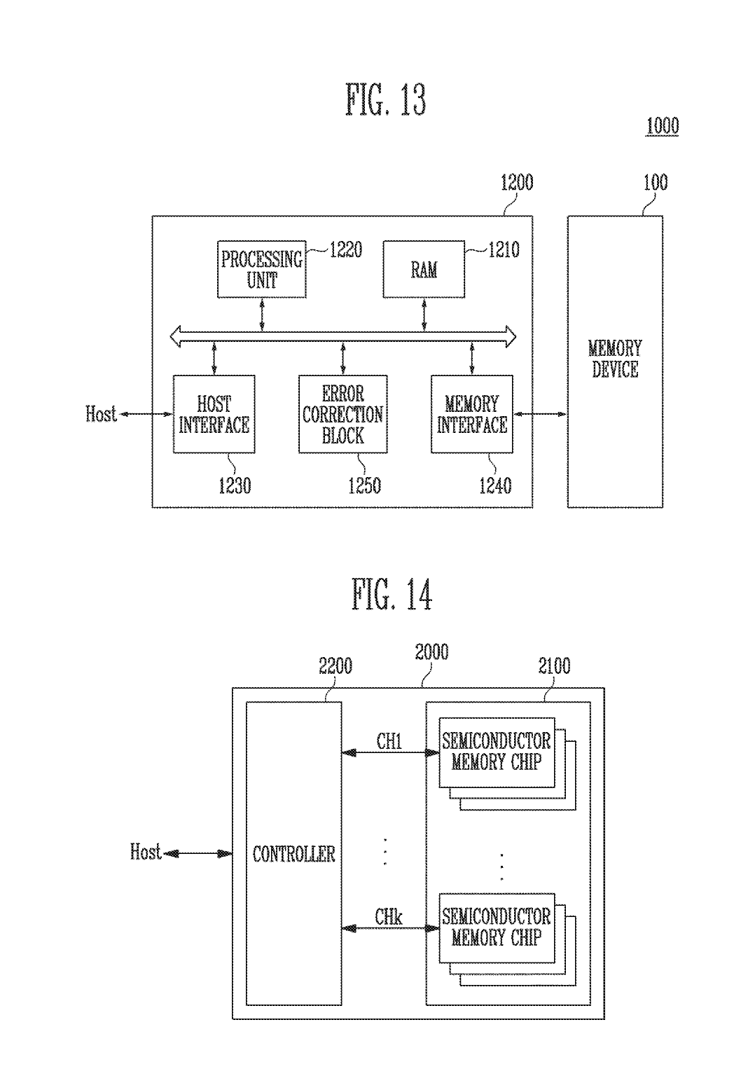

FIG. 13 is a block diagram illustrating a memory system 1000 including the memory device 100 of FIG. 3.

Referring to FIG. 13, the memory system 1000 may include a memory device 100 and a controller 1200.

The memory device 100 may have the same configuration and operation as the memory device, described above with reference to FIG. 1. Hereinafter, repetitive explanations will be omitted.

The controller 1200 is coupled to a host and the memory device 100. The controller 1200 is configured to access the memory device 100 in response to a request from the host. For example, the controller 1200 may control read, write, erase, and background operations of the memory device 100. The controller 1200 may provide an interface between the host and the memory device 100. The controller 1200 may run firmware for controlling the memory device 100.

The controller 1200 includes a RAM (Random Access Memory) 1210, a processing unit 1220, a host interface 1230, a memory interface 1240, and an error correction block 1250.

The RAM 1210 is used as at least one of an operation memory of the processing unit 1220, a cache memory between the memory device 100 and the host, and a buffer memory between the memory device 100 and the host.

The processing unit 1220 controls the overall operation of the controller 1200.

The host interface 1230 includes a protocol for performing data exchange between the host Host and the controller 1200. In an exemplary embodiment, the controller 1200 is configured to communicate with the host Host through at least one of various interface protocols such as a universal serial bus (USB) protocol, a multimedia card (MMC) protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, and an integrated drive electronics (IDE) protocol, and a private protocol.

The memory interface 1240 interfaces with the memory device 100. For example, the memory interface includes a NAND interface or NOR interface.

The error correction block 1250 uses an error correcting code (ECC) to detect and correct an error in data received from the memory device 100.

The memory device 100, described with reference to FIGS. 1 to 12, is provided, and thus the memory system 1000 having improved operating speed may be provided.

The controller 1200 and the memory device 100 may be integrated into a single semiconductor device. In an exemplary embodiment, the controller 1200 and the memory device 100 may be integrated into a single semiconductor device to form a memory card. For example, the controller 1200 and the memory device 100 may be integrated into a single semiconductor device and form a memory card such as a personal computer memory card international association (PCMCIA), a compact flash card (CF), a smart media card (SM or SMC), a memory stick, a multimedia card (MMC, RS-MMC, or MMCmicro), a SD card (SD, miniSD, microSD, or SDHC), or a universal flash storage (UFS).

The controller 1200 and the memory device 100 may be integrated into a single semiconductor device to form a solid state drive (SSD). The SSD includes a storage device configured to store data in a semiconductor memory. When the memory system 1000 is used as the SSD, an operation speed of the host Host coupled to the memory system 1000 may be phenomenally improved.

In other embodiments, the memory system 1000 may be provided as one of various elements of an electronic device such as a computer, a ultra mobile PC (UMPC), a workstation, a net-book, a personal digital assistants (PDA), a portable computer, a web tablet, a wireless phone, a mobile phone, a smart phone, an e-book, a portable multimedia player (PMP), a game console, a navigation device, a black box, a digital camera, a 3-dimensional television, a digital audio recorder, a digital audio player, a digital picture recorder, a digital picture player, a digital video recorder, a digital video player, a device capable of transmitting/receiving information in an wireless environment, one of various devices for forming a home network, one of various electronic devices for forming a computer network, one of various electronic devices for forming a telematics network, an RFID device, one of various elements for forming a computing system, or the like.

In an exemplary embodiment, the memory device 100 or the memory system may be embedded in various types of packages. For example, the memory device 100 or the memory system may be packaged in a type such as Package on Package (PoP), Ball grid arrays (BGAs), Chip scale packages (CSPs), Plastic Leaded Chip Carrier (PLCC), Plastic Dual In Line Package (PDIP), Die in Waffle Pack, Die in Wafer Form, Chip On Board (COB), Ceramic Dual In Line Package (CERDIP), Plastic Metric Quad Flat Pack (MQFP), Thin Quad Flatpack (TQFP), Small Outline Integrated Circuit (SOIC), Shrink Small Outline Package (SSOP), Thin Small Outline Package (TSOP), Thin Quad Flatpack (TQFP), System In Package (SIP), Multi-Chip Package (MCP), Wafer-level Fabricated Package (WFP), Wafer-Level Processed Stack Package (WSP), or the like.

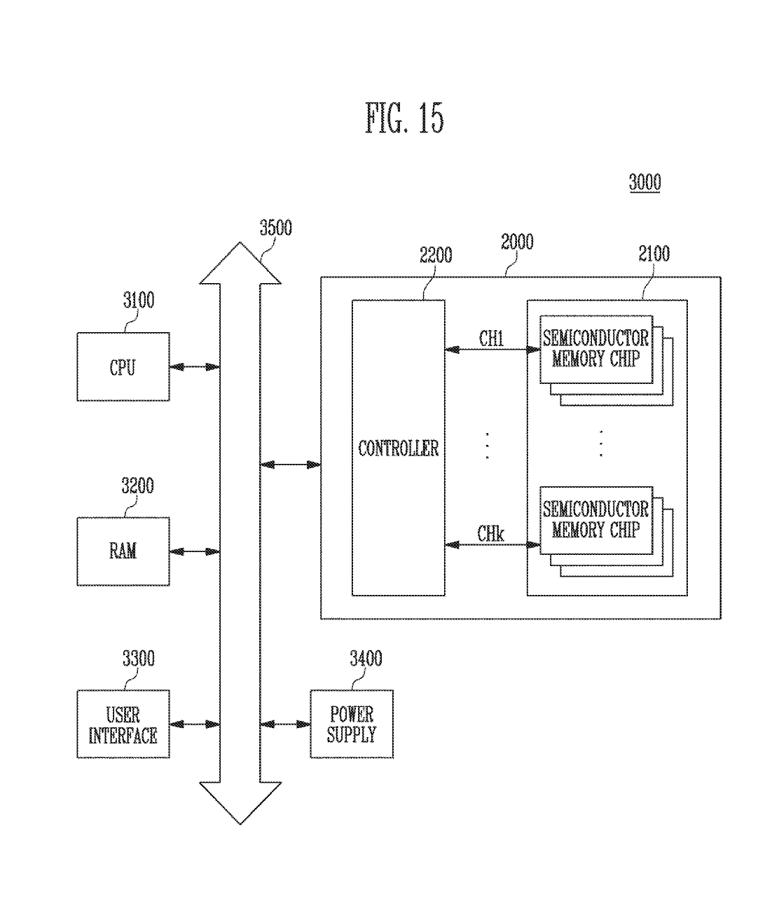

FIG. 14 is a block diagram illustrating an example 2000 of application of the memory system 1000 of FIG. 13.

Referring to FIG. 14, the memory system 2000 includes a memory device 2100 and a controller 2200. The memory device 2100 includes a plurality of semiconductor memory chips. The semiconductor memory chips are divided into a plurality of groups.

In FIG. 14, it is illustrated that each of the plurality of groups communicates with the controller 2200 through first to k-th channels CH1 to CHk. Each semiconductor memory chip may have the same configuration and operation as those of an embodiment of the memory device 100 described with reference to FIG. 1.

Each group communicates with the controller 2200 through one common channel. The controller 2200 has the same configuration as that of the controller 1200 described with reference to FIG. 13 and is configured to control the plurality of memory chips of the memory device 2100 through the plurality of channels CH1 to CHk.

In FIG. 14, a description has been made such that a plurality of semiconductor memory chips are coupled to a single channel. However, it will be understood that the memory system 2000 may be modified such that a single semiconductor memory chip is coupled to a single channel.

FIG. 15 is a block diagram illustrating a computing system 3000 including the memory system 2000 described with reference to FIG. 14.

Referring to FIG. 15, the computing system 3000 may include a central processing unit (CPU) 3100, a RAM 3200, a user interface 3300, a power supply 3400, a system bus 3500, and a memory system 2000.

The memory system 2000 is electrically coupled to the CPU 3100, the RAM 3200, the user interface 3300, and the power supply 3400 through the system bus 3500. Data provided through the user interface 3300 or processed by the CPU 3100 is stored in the memory system 2000.

In FIG. 15, the memory device 2100 is illustrated as being coupled to the system bus 3500 through the controller 2200. However, the memory device 2100 may be directly coupled to the system bus 3500. The function of the controller 2200 may be performed by the CPU 3100 and the RAM 3200.

In FIG. 15, the memory system 2000 described with reference to FIG. 14 is illustrated as being provided. However, the memory system 2000 may be replaced with the memory system 1000 described with reference to FIG. 13. In an embodiment, the computing system 3000 may be configured to include all of the memory systems 1000 and 2000 described with reference to FIGS. 13 and 14.

In accordance with the present disclosure, there are provided a memory device for performing a background erase operation and a method of operating the memory device.

While the exemplary embodiments of the present disclosure have been disclosed for illustrative purposes, those skilled in the art will appreciate that various modifications, additions and substitutions are possible. Therefore, the scope of the present disclosure must be defined by the appended claims and equivalents of the claims rather than by the description preceding them.

Although specific embodiments of the present disclosure have been disclosed, those skilled in the art will appreciate that various modifications, additions and substitutions are possible, without departing from the scope and spirit of the present disclosure.

Therefore, the scope of the present disclosure must be defined by the appended claims and equivalents of the claims rather than by the description preceding them.

In the above-discussed embodiments, all steps may be selectively performed or skipped. In addition, the steps in each embodiment may not always be sequentially performed in regular order, and may be performed in another order. Furthermore, the embodiments disclosed in the present specification and the drawings aims to help those with ordinary knowledge in this art more clearly understand the present disclosure rather than aiming to limit the bounds of the present disclosure. In other words, one of ordinary skill in the art to which the present disclosure belongs will be able to easily understand that various modifications are possible based on the technical scope of the present disclosure.

Embodiments of the present disclosure have been described with reference to the accompanying drawings, and specific terms or words used in the description should be construed in accordance with the spirit of the present disclosure without limiting the subject matter thereof. It should be understood that many variations and modifications of the basic inventive concept described herein will still fall within the spirit and scope of the present disclosure as defined in the appended claims and their equivalents.

What is claimed is:

1. A memory device, comprising:
a memory cell array including a plurality of memory cells;
a peripheral circuit configured to perform a background erase operation on memory cells selected from among the plurality of memory cells; and
a control logic configured to control, when a foreground operation command is inputted while the background erase operation is being performed, the peripheral circuit so that the background erase operation is suspended in response to input of a confirm command for the foreground operation command.

2. The memory device according to claim wherein the foreground operation command includes a first command and a second command indicating that all of addresses and data required to execute the first command have been inputted.

3. The memory device according to claim 2, wherein:
the first command is a start command indicating a type of the foreground operation command, and
the second command is the confirm command.

4. The memory device according to claim 1, wherein the foreground operation command is a command corresponding to any one of a program operation, a read operation, and an erase operation.

5. The memory device according to claim 1, wherein the control logic stores background erase status information that indicates a degree to which the erase operation progresses at a time at which the background erase operation is suspended.

6. The memory device according to claim 5, wherein the control logic controls the peripheral circuit so that the suspended background erase operation resumes based on the background erase status information when execution of the foreground operation command is completed.

7. The memory device according to claim 5, wherein the background erase status information is information indicating at least one of a number of applications of an erase voltage pulse, a number of performed erase loops, a voltage level of the applied erase voltage pulse, and a result of erase verification.

8. The memory device according to claim 1, wherein the memory device receives the foreground operation command from an external controller while the background erase operation is being performed.

9. The memory device according to claim 1, wherein the control logic comprises:
a command decoder configured to output a background trigger signal in response to a background erase command corresponding to the background erase operation and the confirm command, the background erase command and the confirm command being inputted from an external controller; and
a background erase operation control unit configured to perform the background erase operation or suspend the background erase operation in response to the background trigger signal.

10. The memory device according to claim 9, further comprising a status register configured to store a status value determined depending on status information of the memory device,
wherein the background erase operation control unit resumes the background erase operation based on the status value.

11. The memory device according to claim 10, wherein the control logic further comprises a status information register configured to store background erase status information that indicates a degree to which the erase operation progresses at a time at which the background erase operation is suspended.

12. A method of operating a memory device including a plurality of memory cells, comprising:
receiving a background erase command for memory cells selected from among the plurality of memory cells from an external controller;
performing a background erase operation on the selected memory cells;
receiving a foreground operation command for any memory cells, among the plurality of memory cells while the background erase operation is being performed; and
suspending the background erase operation in response to input of a confirm command for the foreground operation command.

13. The method according to claim 12, wherein the foreground operation command includes a first command and a second command indicating that all of addresses and data required to execute the first command have been inputted.

14. The method according to claim 13, wherein:
the first command is a start command indicating a type of the foreground operation command, and
the second command is the confirm command.

15. The method according to claim 12, wherein the foreground operation command is a command corresponding to any one of a program operation, a read operation, and an erase operation.

16. The method according to claim 12, further comprising storing background erase status information that indicates a degree to which the erase operation progresses at a time at which the background erase operation is suspended.

17. The method according to claim 16, further comprising resuming suspended background erase operation based on the background erase status information when execution of the foreground operation command is completed.

18. The method according to claim 16, wherein the background erase status information is information indicating at least one of a number of applications of an erase voltage pulse, a number of performed erase loops, a voltage level of the applied erase voltage pulse, and a result of erase verification.

19. A memory device comprising:
a plurality of memory cells;
a peripheral circuit configured to perform an operation to the memory cells; and
a control logic configured to control the peripheral circuit to perform a background erase operation while a foreground operation is not performed,
wherein the control logic configured to control the peripheral circuit to keep performing the background erase operation until all information required for performing the foreground operation is provided.
